(19) United States
(12) Patent Application Publication
(10) Pub. No.: US 2026/0107546 A1
(43) Pub. Date: Apr. 16, 2026

(54) SEMICONDUCTOR DEVICE

(71) Applicant: Samsung Electronics Co., Ltd., Suwon-si (KR)

(72) Inventors: Yang XU, Suwon-si (KR); Seokhoon KIM, Suwon-si (KR); Soomin SON, Suwon-si (KR); Sangmoon LEE, Suwon-si (KR); Soobin HAN, Suwon-si (KR)

(21) Appl. No.: 19/199,073

(22) Filed: May 5, 2025

(30) Foreign Application Priority Data
Oct. 15, 2024 (KR) 10-2024-0140565

(51) Int. Cl. H10D 64/23; H10D 30/00; H10D 30/01; H10D 30/43; H10D 62/00; H10D 62/10; H10D 62/13; H10D 84/01; H10D 84/83

(52) U.S. Cl. CPC H10D 64/256; H10D 30/43; H10D 30/502; H10D 62/121; H10D 62/151; H10D 84/8312; H10D 84/832; H10D 30/014; H10D 30/0191; H10D 62/021; H10D 84/013; H10D 84/0149

(57) ABSTRACT

Provided is a semiconductor device including a base pattern, channel layers disposed to be spaced apart from each other in a first direction perpendicular to a frontside of the base pattern on the frontside of the base pattern, a first source/drain area and a second source/drain area electrically connected to the channel layers on the frontside of the base pattern, a backside contact plug electrically connected to the first source/drain area from a backside of the base pattern, and a frontside contact plug electrically connected to the second source/drain area above the frontside of the base pattern, and the first source/drain area includes a first-first layer disposed on side surfaces of the channel layers of which each is perpendicular to a second direction crossing the first direction, and a first-second layer disposed on the first-first layer, and the backside contact plug is spaced apart from the first-first layer.

### CROSS-REFERENCE TO RELATED APPLICATIONS

This application claims priority under 35 USC § 119 to the benefit of Korean Patent Application No. 10-2024-0140565, filed on Oct. 15, 2024, in the Korean Intellectual Property Office, the disclosure of which is incorporated herein by reference in its entirety.

### BACKGROUND

### 1. Field of the Invention

The present disclosure relates to a semiconductor device.

### 2. Description of the Related Art

A fin field-effect transistor (FinFET) and a nanosheet field-effect transistor have been adopted as a technology for an integrated circuit having highly integrated devices and high performance. The FinFET includes a channel layer of which at least three surfaces are surrounded by a gate structure and has one or more horizontally arranged vertical fin structures. A gate-all-around (GAA) transistor or a multi-bridge channel transistor is known as an example of the nanosheet field-effect transistor, and the nanosheet field-effect transistor includes one or more nanosheet channel layers vertically stacked on a substrate and a gate structure surrounding each nanosheet channel layers.

In order to solve routing complexity and prevent an excessive descent of voltage at a frontside of a field-effect transistor, a backside power distribution network (BSPDN) in which at least a portion of back-end of line (BEOL) is formed at a backside of the field-effect transistor has been adopted. The backside power distribution network may include a backside wiring line that supplies voltage to a source/drain area of the field-effect transistor.

The backside power distribution network may be directly connected to the source/drain area through a backside contact plug or the like (e.g., a direct backside contact (DBC)). The source/drain area may include a first layer disposed at an edge at least and a second layer that fills an area other than an area in which the first layer is disposed. Here, the first layer and the second layer may include silicon (Si), and each of the first layer and the second layer may be doped with an impurity (e.g., germanium (Ge)). For example, an epitaxial growth scheme may be applied to the source/drain area, and the first layer may be a foundation/seed layer for growing the second layer that substantially performs a source/drain function. Due to a difference in impurity concentration, the first layer and the second layer may have different contact resistances R_{cnt} at contact areas being in contact with the backside contact plug. In some cases, since a concentration of an impurity of the first layer is lower than a concentration of an impurity of the second layer, and since the backside contact plug is always unavoidably in contact with the first layer when being directly connected to the source/drain area, a contact resistance may be increased when compared with a case of being connected only to the second layer.

In a gate structure, a spacer may be disposed between a gate electrode and the source/drain area. In this case, since the gate electrode and the second layer that substantially performs the source/drain function are not in contact with each other due to the spacer, the second layer may be grown after the first layer is grown in a bottom area. Since the first layer is formed only in the bottom area, the backside contact plug may be connected to or contact the second layer after the first layer is completely removed. However, since being grown on a wide layer/area with various surface properties, such as a side surface of the spacer, the second layer is grown to be defective and not to be conformal. In this case, an increase in the contact resistance R_{cnt} may be prevented because the backside contact plug is not in contact with the first layer. However, since the second layer that substantially performs the source/drain function is grown to be defective and does not apply quantum stress to a channel layer, a degree of movement of an electron in channel layers may not be improved.

When the first layer is formed and grown not only in the bottom area but also at the edge including a side surface area, the second layer may be grown to be conformal to apply the quantum stress to the channel layers. However, since the backside contact plug is to be necessarily in contact with the first layer in order to be in contact with the second layer, the contact resistance R_{cnt} may be increased.

### SUMMARY

An aspect of the present disclosure provides a semiconductor device that minimizes a contact resistance at a contact area at which a backside contact plug is in contact with a source/drain area and in which the source/drain area applies sufficient quantum stress to improve a degree of movement of an electron in channel layers.

However, the goals to be achieved by example embodiments of the present disclosure are not limited to the objectives described above and other objects may be clearly understood from the following example embodiments by those skilled in the art.

According to an aspect, there is provided a semiconductor device including a base pattern, channel layers disposed to be spaced apart from each other in a first direction perpendicular to a frontside of the base pattern on the frontside of the base pattern, an inner gate structure disposed between the channel layers, a first source/drain area electrically connected to the channel layers on the frontside of the base pattern, a second source/drain area spaced apart from the first source/drain area in a second direction crossing the first direction and electrically connected to the channel layers on the frontside of the base pattern, a backside contact plug electrically connected to the first source/drain area from a backside of the base pattern opposite to the frontside of the base pattern, and a frontside contact plug electrically connected to the second source/drain area on the frontside of the base pattern, and the first source/drain area includes a first-first layer disposed on side surfaces of the channel layers, the side surfaces of the channel layers being perpendicular to the second direction, and a first-second layer disposed on the first-first layer, and the backside contact plug is spaced apart from the first-first layer.

According to another aspect, there is also provide a semiconductor device including a base pattern, a first active pattern formed in a first active area extending in a second direction on a frontside of the base pattern, a second active pattern spaced apart from the first active pattern in a third direction crossing the second direction and formed in a second active area extending in the second direction on the frontside of the base pattern, gate structures disposed to be spaced apart from each other in the second direction on the frontside of the base pattern and crossing each of the first active pattern and the second active pattern, each of the gate structures including an inner gate structure, a backside contact plug, and a frontside contact plug, wherein each of the first active pattern and the second active pattern includes channel layers disposed to be spaced apart from each other in a first direction crossing the second direction and the third direction on the frontside of the base pattern, a first source/drain area connected to the channel layers on the frontside of the base pattern, and a second source/drain area spaced apart from the first source/drain area in the second direction and connected to the channel layers on the frontside of the base pattern, the inner gate structure is disposed between the channel layers, the backside contact plug is connected to the first source/drain area from a backside of the base pattern opposite to the frontside of the base pattern, the frontside contact plug is connected to the second source/drain area on the frontside of the base pattern, each of the first source/drain area of the first active pattern and the first source/drain area of the second active pattern includes a first-first layer disposed on a side surface of each of the channel layers, the side surface of each of the channel layers being perpendicular to the second direction, and a first-second layer disposed on the first-first layer, the backside contact plug in the first active area is spaced apart from the first-first layer of the first source/drain area, and the backside contact plug in the second active area is spaced apart from the first-first layer of the second source/drain area.

According to still another aspect, there is also provided a semiconductor device including a base pattern, a first active pattern extending in a second direction on a frontside of the base pattern, a second active pattern spaced apart from the first active pattern in a third direction crossing the second direction and extending in the second direction on the frontside of the base pattern, gate structures disposed to be spaced apart from each other in the second direction on the frontside of the base pattern and crossing each of the first active pattern and the second active pattern, the gate structures including an inner gate structure, a backside contact plug, and a frontside contact plug, and each of the first active pattern and the second active pattern includes channel layers disposed to be spaced apart from each other in a first direction crossing the second direction and the third direction on the frontside of the base pattern, a first source/drain area contacting the channel layers on the frontside of the base pattern, and a second source/drain area spaced apart from the first source/drain area in the second direction and contacting the channel layers on the frontside of the base pattern, the inner gate structure is disposed between the channel layers, the backside contact plug contacts the first source/drain area from a backside of the base pattern opposite to the frontside of the base pattern, the frontside contact plug contacts the second source/drain area on the frontside of the base pattern, each of the first source/drain area of the first active pattern and the first source/drain area of the second active pattern includes a first-first layer including an impurity and disposed on a side surface of each of the channel layers, the side surface being perpendicular to the second direction, and a first-second layer disposed on the first-first layer and including an impurity of which a concentration is higher than that of the first-first layer, the backside contact plug in the first active area is spaced apart from the first-first layer of the first source/drain area, the backside contact plug in the second active area is spaced apart from the first-first layer of the second source/drain area, at least a portion of the first-first layer of the first source/drain area is disposed to be conformal on side surfaces of the channel layers, as approaching the frontside of the base pattern, a length in the second direction of an end portion of the first-first layer of the first source/drain area, which is adjacent to the frontside of the base pattern, is gradually decreased, the end portion of the first-first layer of the first source/drain area has a sloped surface having an acute slope angle with respect to the side surfaces of the channel layers, at least a portion of the first-first layer of the second source/drain area is disposed to be conformal on the side surfaces of the channel layers, as approaching the frontside of the base pattern, a length in the second direction of an end portion of the first-first layer of the second source/drain area, which is adjacent to the frontside of the base pattern, is gradually decreased, and the end portion of the first-first layer of the second source/drain area has a sloped surface having an acute slope angle with respect to the side surfaces of the channel layers.

Additional aspects of example embodiments will be set forth in part in the description which follows and, in part, will be apparent from the description.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example layout diagram illustrating a semiconductor device according to an example embodiment of the present disclosure;

FIG. 2 is an example diagram illustrating a cross section taken along a line A-A′ of FIG. 1;

FIG. 3 is a diagram illustrating a cross section taken along a line A-A′ of FIG. 1 and an example diagram illustrating a shape of a frontside wiring line, a frontside wiring via, and a frontside contact plug;

FIG. 4 is an example enlargement diagram illustrating an enlargement of a part P of FIG. 2;

FIG. 5 is an example diagram illustrating a cross section taken along a line B-B′ of FIG. 1;

FIG. 6 is a diagram illustrating a cross section taken along a line B-B′ of FIG. 1 and an example diagram illustrating a shape of a frontside wiring line, a frontside wiring via, and a frontside contact plug;

FIG. 7 is an example diagram illustrating a cross section taken along a line C-C′ of FIG. 1;

FIG. 8 is an example diagram illustrating a cross section taken along a line D-D′ of FIG. 1;

FIG. 9 is an example diagram illustrating a cross section taken along a line E-E′ of FIG. 1;

FIG. 10 is an example layout diagram illustrating a semiconductor device according to an example embodiment of the present disclosure;

FIG. 11 is an example diagram illustrating a cross section taken along a line F-F′ of FIG. 10;

FIG. 12 is a diagram illustrating a cross section taken along a line A-A′ of FIG. 1 and an example diagram illustrating a shape in which a first-first layer and a second-first layer are grown;

FIG. 13 is a diagram illustrating a cross section taken along a line A-A′ of FIG. 1 and an example diagram illustrating a shape in which a damaged first-first layer and a damaged second-first layer are formed by damaging a portion of a first-first layer and a second-first layer through an ion implantation process (IIP);

FIG. 14 is a diagram illustrating a cross section taken along a line A-A′ of FIG. 1 and an example diagram illustrating a shape in which a damaged first-first layer and a damaged second-first layer that are damaged through an ion implantation process (IIP) are removed;

FIG. 15 is a diagram illustrating a cross section taken along a line A-A′ of FIG. 1 and an example diagram illustrating a shape in which a recessed first-first layer and a recessed second-first layer formed by removing a portion of a first-first layer and a second-first layer through an etching process;

FIG. 16 is a diagram illustrating a cross section taken along a line A-A′ of FIG. 1 and an example diagram illustrating a shape in which a first-second layer and a second-second layer are grown;

FIG. 17 is a diagram illustrating a cross section taken along a line A-A′ of FIG. 1 and an example diagram illustrating a shape in which a frontside contact plug is formed on a second-second layer; and

FIG. 18 is a diagram illustrating a cross section taken along a line A-A′ of FIG. 1 and an example diagram illustrating a shape in which a backside contact plug is formed on a first-second layer.

### DETAILED DESCRIPTION

Before the present disclosure is described, terms or words used in the present disclosure and the accompanying claims are not to be limited to general definitions or dictionary definitions. The terms and words are to be construed under a principle that an inventor may appropriately define a concept of a term in order to describe their invention in the best way. Example embodiments described in the present disclosure and configurations illustrated in the accompanying drawings are merely the most desirable example embodiments and do not represent all of the technical spirit of the present disclosure. Thus, it should be understood that various equivalents and modifications that may replace the example embodiments and configurations may be present at the time of filing the application of the present disclosure.

The same reference numerals or symbols illustrated in the accompanying drawings represent components or elements performing substantially identical or identical functions. For convenience for description and understanding, example embodiments different from each other may be described with the same reference numerals or symbols. For example, although a plurality of drawings illustrates elements having the same reference numeral, the plurality of drawings does not mean the same example embodiment, but may illustrate different embodiments from each other.

In the present disclosure, when an element is described as being “directly on” or “in contact with” another element, it may be understood that the element is connected to the other element and no other element is present between them. For example, it will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

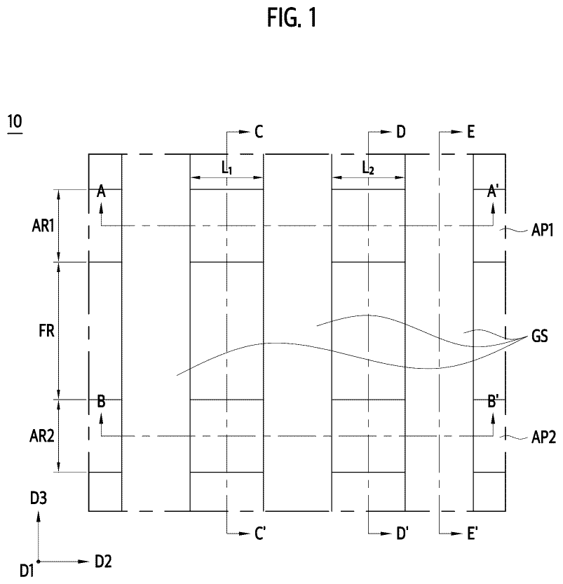

Also, in the present disclosure, when an element is described as being “above” or “on an upper surface of” another element, it may be understood that the element is present over the other element in a vertical direction. For example, the element may be understood as being over the other element in the vertical direction (e.g., a direction D1 in FIG. 1). They may be in contact with or directly connected to each other, or it may be understood that still another element may be present between them. This may be similarly applied to a case in which an element is described as being “over” another element.

In addition, in the present disclosure, when an element is described as being “below” or “on a lower surface of” another element, it may be understood that the element is present under the other element in a vertical direction. For example, the element may be understood as being under the other element in the vertical direction (e.g., the direction D1 in FIG. 1). They may be in contact with or directly connected to each other, or it may be understood that still another element may be present between them. This may be similarly applied to a case in which an element is described as being “under” another element.

Other expressions for describing relationship of positions between elements may be construed similarly to the above.

In the following descriptions, terms of singular form include terms of plural form unless an apparently and contextually conflicting description is present. Terms such as “including” or “comprising” is to indicate that a feature, a number, an operation, an action, an element, a component, or a combination thereof is present. It should be understood that the terms are not to exclude a possibility that one or more other features, numbers, operations, actions, elements, components, or combinations thereof may be present or added.

In addition, it should be noted in advance that an expression such as an upper side, an upper surface, a lower side, a lower surface, a side surface, a front surface, or a rear surface is based on directions illustrated in the drawings and that the expression may be changed when a direction of a corresponding object is changed. This is also applied to other spatially relative terms.

Terms including an ordinal number such as “first” or “second” used in the present specification and claims may be used to distinguish elements. Such an ordinal number is used to contextually distinguish identical or similar elements from each other. Meanings of the terms may not be limited by use of the ordinal number. For example, a use order, a disposition order, or the like of elements with such an ordinal number may not be limitedly construed by the number. For example, ordinal numbers may be interchanged with each other.

A physical property described in the present disclosure may be measured at normal temperature and pressure unless specifically limited. The normal temperature in the present disclosure may be a room temperature or non-manipulated natural temperature within a range from 10 degrees Celsius (° C.) to 30° C., from 20° C. to 28° C., or from 22° C. to 26° C. In an example embodiment, the normal temperature may be 25° C. The normal pressure in the present disclosure may be an atmospheric pressure or non-manipulated natural pressure within a range from 700 millimeters of mercury (mmHg) to 800 mmHg or from 720 mmHg to 780 mmHg. In an example embodiment, the normal pressure may be 760 mmHG.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Hereinafter, the example embodiments of the present disclosure will be described with reference to the drawings. FIG. 1 is an example layout diagram illustrating a semiconductor device 10 according to an example embodiment of the present disclosure. In an example embodiment, the semiconductor device 10 may include one or more of a fin field-effect transistor and a nanosheet field-effect transistor, but the inventive concept is not limited thereto. The semiconductor device 10 illustrated in the drawings show examples and the inventive concept is not limited thereto.

In addition, the semiconductor device 10 may include one or more of a tunneling field-effect transistor (FET), a three-dimensional transistor, and a vertical FET. The semiconductor device 10 may include a planar transistor in certain embodiments. In an example embodiment, the semiconductor device 10 may be applied to a two-dimensional (2D) material-based FET and a heterostructure thereof. The semiconductor device 10 according to an example embodiment may include a bipolar junction transistor, a lateral double-diffused transistor (e.g., a laterally-diffused metal-oxide semiconductor (LDMOS) transistor), or the like.

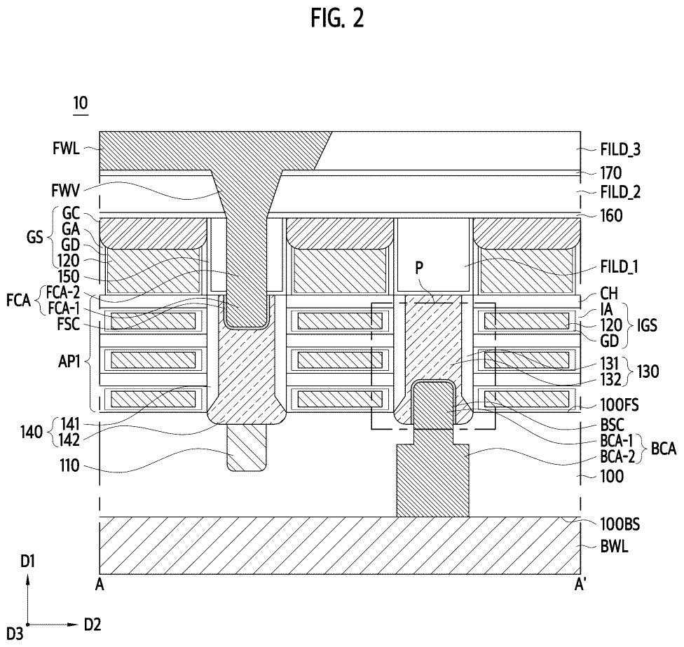

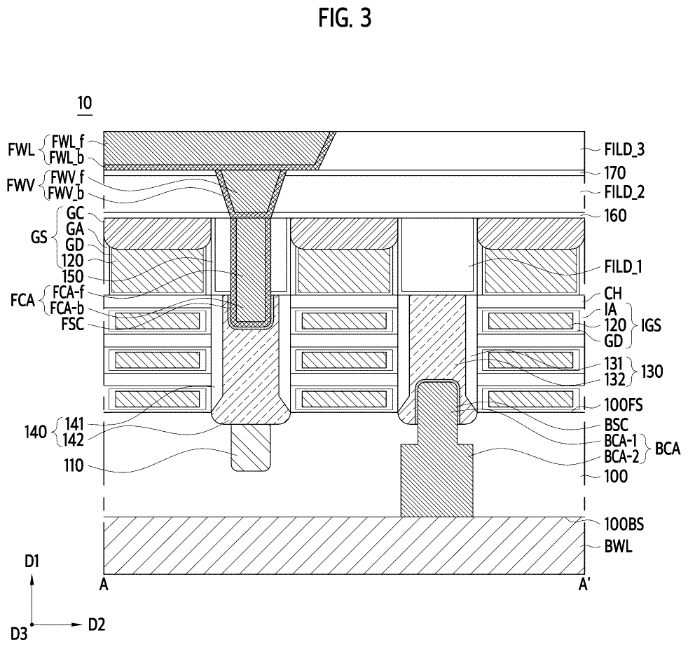

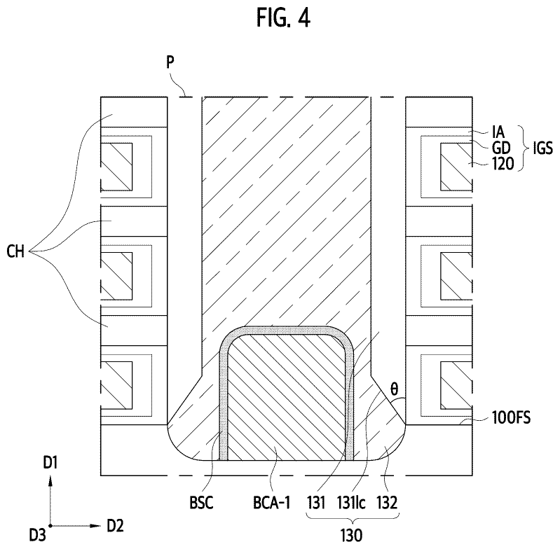

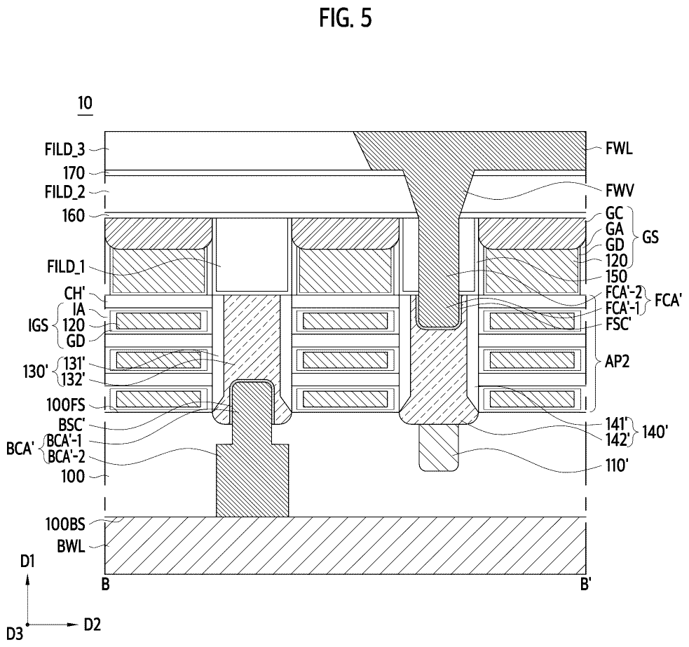

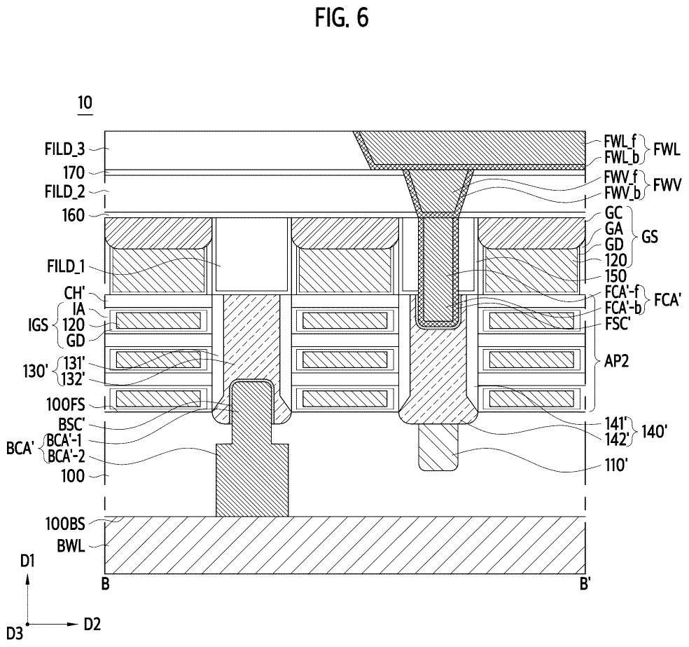

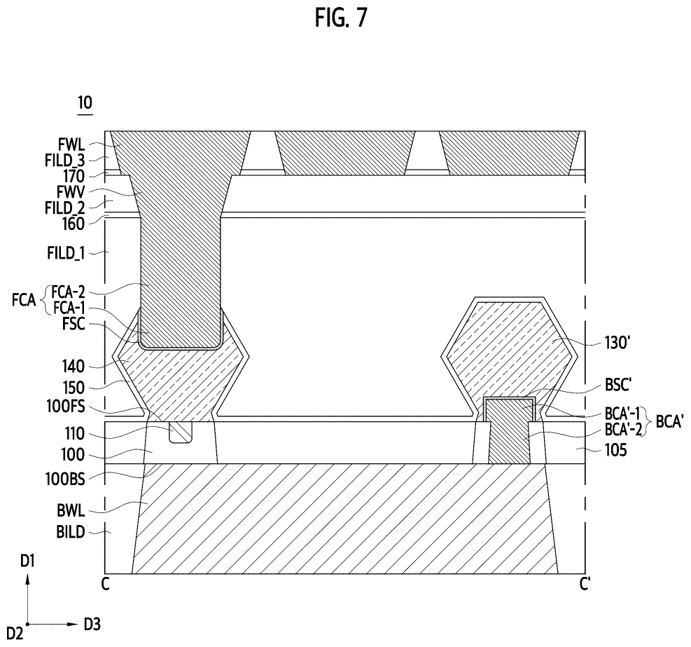

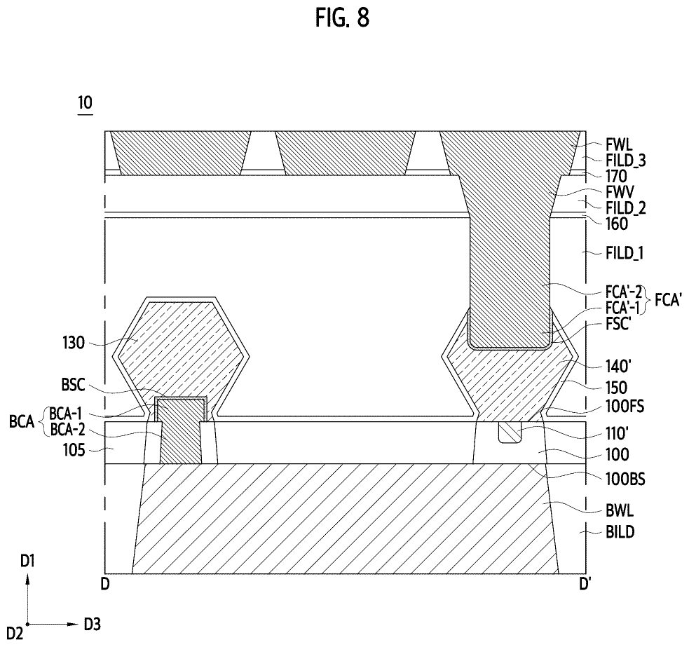

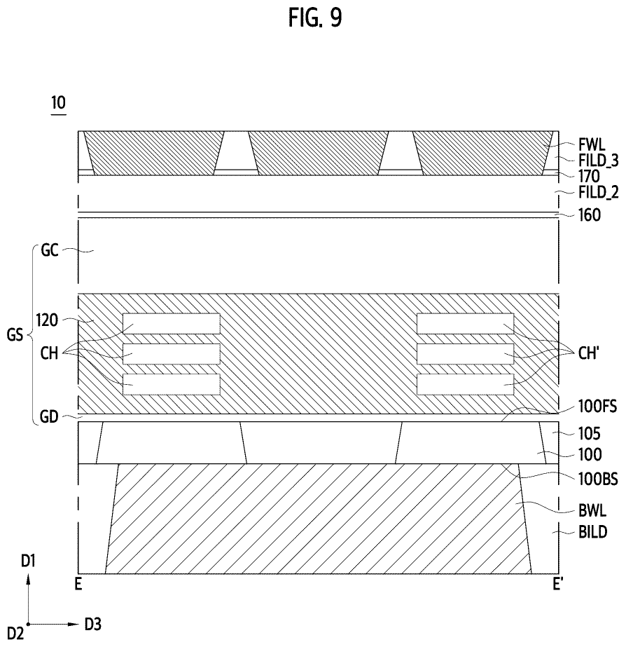

FIG. 2 is an example diagram illustrating a cross section taken along a line A-A′ of FIG. 1. FIG. 3 is a diagram illustrating a cross section taken along the line A-A′ of FIG. 1 and an example diagram illustrating a shape of a frontside wiring line FWL, a frontside wiring via FWV, and a frontside contact plug FCA. FIG. 4 is an example enlargement diagram illustrating an enlargement of a part P of FIG. 2. FIG. 5 is an example diagram illustrating a cross section taken along a line B-B′ of FIG. 1. FIG. 6 is a diagram illustrating a cross section taken along the line A-A′ of FIG. 1 and an example diagram illustrating a shape of the frontside wiring line FWL, the frontside wiring via FWV, and the frontside contact plug FCA. FIG. 7 is an example diagram illustrating a cross section taken along a line C-C′ of FIG. 1. FIG. 8 is an example diagram illustrating a cross section taken along a line D-D′ of FIG. 1. FIG. 9 is an example diagram illustrating a cross section taken along a line E-E′ of FIG. 1.

A first direction D1 in the present disclosure may be a direction perpendicular to a frontside 100FS of a base pattern. The frontside 100FS of the base pattern may be an upper surface of the base pattern. A second direction D2 may be a direction crossing the first direction D1. In an example embodiment, the second direction D2 may be identical or parallel to a horizontal direction of the frontside 100FS of the base pattern. A third direction D3 may be a direction crossing the first direction D1 and the second direction D2. In an example embodiment, the third direction D3 may be identical or parallel to the horizontal direction of the frontside 100FS of the base pattern. In an example embodiment, the first direction D1 and the second direction D2 may be perpendicular to each other, the second direction D2 and the third direction D3 may be perpendicular to each other, and the third direction D3 and the first direction D1 may be perpendicular to each other.

In an example embodiment, the semiconductor device 10 may include a base pattern 100, channel layers CH and CH′, an inner gate structure IGS, first source/drain areas 130 and 130′, second source/drain areas 140 and 140′, backside contact plugs BCA and BCA′, and frontside contact plugs FCA and FCA′.

In an example embodiment, the base pattern 100 may be disposed on a backside inter-layer insulation film BILD. The base pattern 100 may be disposed below a first active pattern AP1 and a second active pattern AP2. For example, the base pattern 100 may be disposed between the backside inter-layer insulation film BILD and the first active pattern AP1. The base pattern 100 may be dispose between the backside inter-layer insulation film BILD and the second active pattern AP2. The backside inter-layer insulation film BILD may be a single layer in an example embodiment and may have a plurality of layers having a stack structure in another example embodiment. The backside inter-layer insulation film BILD may include an insulation material. The backside inter-layer insulation film BILD may include one or more selected from a group including silicon oxide, silicon-germanium oxide, germanium oxide, silicon oxynitride, silicon nitride, and a low-permittivity material.

In the present disclosure, the insulation material may include one or more selected from a group including silicon oxide, silicon-germanium oxide, germanium oxide, silicon oxynitride, silicon nitride, a high-permittivity material having a dielectric constant higher than that of silicon oxide, and a low-permittivity material having a dielectric constant lower than that of silicon oxide. The high-permittivity material may include, for example, one or more from a group including boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but the inventive concept is not limited thereto. The low-permittivity material may include, for example, one or more from a group including fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica, but the inventive concept is not limited thereto.

In an example embodiment, the base pattern 100 may include a semiconductor material. The base pattern 100 may be a silicon substrate or silicon-on-insulator (SOI). The base pattern 100 may include silicon germanium on insulator (SGOI), indium antimonide, lead telluride, indium arsenide, gallium arsenide, or gallium antimonide, but the material of the base pattern 100 is not limited thereto. In another example embodiment, the base pattern 100 may include at least one of silicon oxide, silicon nitride, silicon oxynitride, and a low-permittivity material.

In an example embodiment, the semiconductor device 10 may include a first active area AR1, a second active area AR2, and a field area FR. In an example embodiment, each of the first active area AR1 and the second active area AR2 may be extended, e.g., lengthwise, in the second direction D2. The first active area AR1 and the second active area AR2 may be spaced apart from each other in the third direction D3. In an example embodiment, the field area FR may be disposed between the first active area AR1 and the second active area AR2 to separate the first active area AR1 and the second active area AR2. The field area FR may form a boundary between the first active area AR1 and the second active area AR2.

In an example embodiment, an element separation film (not illustrated) may be disposed around the first active area AR1 and around the second active area AR2 spaced apart from each other. An area of the element separation film, which is between the first active area AR1 and the second active area AR2, may be the field area FR. In an example embodiment, in the semiconductor device 10, an area in which channel layers CH are formed may be active areas AR1 and AR2, and an area dividing the channel layers CH formed in the active areas AR1 and AR2 may be the field area FR. For example, the active areas AR1 and AR2 may be an area in which a fin-shaped pattern or a nanosheet applied as the channel layers CH of a transistor is formed, and the field area FR may be an area in which the fin-shaped pattern or the nanosheet applied as the channel layers CH is not formed. It is apparent that those skilled in the art to which the present disclosure belongs may distinguish what portion the field area FR is and what portion the active areas AR1 and AR are.

In an example embodiment, the first active area AR1 and the second active area AR2 may be areas in which at least a portion of a p-channel metal-oxide semiconductor (PMOS) is formed. In an example embodiment, the first active area AR1 and the second active area AR2 may be an areas in which at least a portion of an n-channel metal-oxide semiconductor (NMOS) is formed. In an example embodiment, one of the first active area AR1 and the second active area AR2 may be an area in which at least a portion of the PMOS is formed, and the other thereof may be an area in which at least a portion of the NMOS is formed.

In an example embodiment, the first active area AR1 may include the first active pattern AP1 which is disposed in one direction (e.g., the second direction D2) on the frontside 100FS of the base pattern. The second active area AR2 may include the second active pattern AP2 which is disposed in one direction (e.g., the second direction D2) on the frontside 100FS of the base pattern. The first active pattern AP1 and the second active pattern AP2 may be spaced apart from each other in a direction (e.g., the third direction D3) crossing disposition directions thereof.

According to some example embodiments, each of the first active pattern AP1 and the second active pattern AP2 may have an upper surface and a lower surface opposite each other in the first direction D1. The lower surface of each of the first active pattern AP1 and the second active pattern AP2 may face the base pattern 100.

In an example embodiment, the first active pattern AP1 and the second active pattern AP2 may respectively include the channel layers CH and CH′ spaced apart from each other in the first direction D1 on the frontside 100FS of the base pattern. In the drawings, the channel layers CH of the first active pattern AP1 and channel layers CH′ of the second active pattern AP2 are illustrated as each including three nano-sheets. However, this is merely for convenience for description, and the inventive concept is not limited thereto.

In an example embodiment, the channel layers CH of the first active pattern AP1 and the channel layers CH′ of the second active pattern AP2 may be independently include one or more of silicon (Si) and germanium (Ge). In an example embodiment, the channel layers CH of the first active pattern AP1 and the channel layers CH′ of the second active pattern AP2 may include a compound semiconductor, for example, may include a group IV-IV compound semiconductor or a group III-V compound semiconductor. In an example embodiment, the group IV-IV compound semiconductor may be a binary compound or a ternary compound including at least two of carbon (C), silicon (Si), germanium (Ge), and tin (Sn) or may be a compound obtained by doping the above-described compounds with a group IV element. In an example embodiment, the group III-V compound semiconductor may be, for example, one of a binary compound, a ternary compound, or a quaternary compound formed in combination of at least one of aluminum (Al), gallium (Ga), and indium (In) of group III elements and one of phosphorus (P), arsenic (As), and antimony (Sb) of group V elements.

In an example embodiment, a field insulation film 105 may be disposed in the field area FR. The field insulation film 105 may be disposed on the backside inter-layer insulation film BILD. In an example embodiment, the field insulation film 105 may surround at least a portion of a side surface of the base pattern 100. For example, the field insulation film 105 contact the side surface of the base pattern 100. The field insulation film 105 may include an insulation material. In an example embodiment, the field insulation film 105 may include an insulation material identical to that included in the base pattern 100. In this case, a boundary between the field insulation film 105 and the base pattern 100 may not clearly appear, and the base pattern 100 and the field insulation film 105 may be regarded as one body.

In an example embodiment, the first active pattern AP1 and the second active pattern AP2 may respectively include the first source/drain areas 130 and 130′ electrically connected to and/or contacting the channel layers CH and CH′ on the frontside 100FS of the base pattern. The first active pattern AP1 and the second active pattern AP2 may respectively include the second source/drain areas 140 and 140′ spaced apart from the first source/drain areas 130 and 130′ in the second direction D2 and electrically connected to and/or contacting the channel layers CH and CH′ on the frontside 100FS of the base pattern.

In an example embodiment, a first source/drain area 130 and a second source/drain area 140 of the first active pattern AP1 may have an identical conductivity type. In an example embodiment, the first source/drain area 130 and the second source/drain area 140 of the first active pattern AP1 may be N-type or P-type. In an example embodiment, the first source/drain area 130 and the second source/drain area 140 of the first active pattern AP1 may have different conductivity types from each other. For example, one of the first source/drain area 130 and the second source/drain area 140 of the first active pattern AP1 may be N-type, and the other thereof may be P-type. In an example embodiment, each of the first source/drain area 130 and the second source/drain area 140 may include an impurity, and a type of the impurity may vary depending on a conductivity type. For example, an N-type source/drain area may include an N-type dopant that is an impurity including at least one of phosphorus (P), arsenic (As), antimony (Sb), and bismuth (Bi), and a P-type source/drain area may include a P-type dopant that is an impurity including at least one of boron (B) and Gallium (Ga).

In an example embodiment, a first source/drain area 130′ and a second source/drain area 140′ of the second active pattern AP2 may have an identical conductivity type. In an example embodiment, the first source/drain area 130′ and the second source/drain area 140′ of the second active pattern AP2 may be N-type or P-type. In an example embodiment, the first source/drain area 130′ and the second source/drain area 140′ of the second active pattern AP2 may have different conductivity types from each other. For example, one of the first source/drain area 130′ and the second source/drain area 140′ of the second active pattern AP2 may be N-type, and the other thereof may be P-type. In an example embodiment, each of the first source/drain area 130′ and the second source/drain area 140′ may include an impurity, and as described above, a type of the impurity may vary depending on a conductivity type.

In an example embodiment, the first source/drain area 130 of the first active pattern AP1 may include a first-first layer 131 disposed on side surfaces of the channel layers CH of which each is perpendicular to the second direction D2 and a first-second layer 132 disposed on the first-first layer 131. In an example embodiment, the first source/drain area 130′ of the second active pattern AP2 may include a first-first layer 131′ disposed on side surfaces of the channel layers CH′ of which each is perpendicular to the second direction D2 and a first-second layer 132′ disposed on the first-first layer 131′.

Referring to FIGS. 2 through 4, a lower side surface of the first-second layer 132 is illustrated as being in contact with an inner spacer IA in the second direction D2. However, the first-first layer 131 may be extended longer in a direction toward a backside wiring line BWL (namely, a direction −D1) to space the first-second layer 132 and the inner spacer IA apart. Such a structure may be identically applied to the first-first layer 131′ and the first-second layer 132′ in FIGS. 5 and 6. For example, lowermost points of first-first layers 131 and 131′ may be positioned below a lowermost surface of a gate insulation film GD in the first direction D1.

In an example embodiment, the first-first layers 131 and 131′ may include silicon (Si) or silicon-germanium (SiGe), but the inventive concept is not limited thereto. In an example embodiment, first-second layers 132 and 132′ may include silicon-germanium (SiGe), but the inventive concept is not limited thereto.

In an example embodiment, the second source/drain area 140 of the first active pattern AP1 may include a second-first layer 141 disposed on side surfaces of the channel layers CH of which each is perpendicular to the second direction D2 and a second-second layer 142 disposed on the second-first layer 141. In an example embodiment, the second source/drain area 140′ of the second active pattern AP2 may include a second-first layer 141′ disposed on side surfaces of the channel layers CH′ of which each is perpendicular to the second direction D2 and a second-second layer 142′ disposed on the second-first layer 141′.

Referring to FIGS. 2 through 4, a lower side surface of the second-second layer 142 is illustrated as being in contact with the inner spacer IA placed adjacent in the second direction D2. However, the second-first layer 141 may be extended longer in the direction toward the backside wiring line BWL (namely, the direction −D1) to space the second-second layer 142 and the inner spacer IA apart. Such a structure may be identically applied to the second-first layer 141′ and the second-second layer 142′ in FIGS. 5 and 6. For example, lowermost points of second-first layers 141 and 141′ may be positioned below the lowermost surface of the gate insulation film GD in the first direction D1. In an example embodiment, the second-first layers 141 and 141′ may include silicon (Si) or silicon-germanium (SiGe), but the inventive concept is not limited thereto. In an example embodiment, second-second layers 142 and 142′ may include silicon-germanium (SiGe), but the inventive concept is not limited thereto.

In an example embodiment, the semiconductor device 10 may include gate structures GS that are disposed to be spaced apart from each other, on the frontside 100FS of the base pattern, in a direction in which the first active pattern AP1 is disposed or extending lengthwise (e.g., the second direction D2) and that are connected to each of the first active pattern AP1 and the second active pattern AP2. Distances between adjacent gate structures GS in the second direction D2 may be the same as each other. In an example embodiment, a gate structure GS may be disposed on the first active pattern AP1 and the second active pattern AP2 and may cross or vertically overlap the first active pattern AP1 and the second active pattern AP2 at a portion thereof. In an example embodiment, the gate structures GS may surround channel layers CH of the first active pattern AP1. In addition, the gate structure GS may surround channel layers CH′ the second active pattern AP2.

In an example embodiment, the number of the gate structures GS may be greater than or equal to three. Spaced distances L1 and L2 between adjacent gate structures GS among the gate structures of which the number is greater than or equal to three may be substantially equal to or the same as each other.

In an example embodiment, the gate structure GS may include a gate electrode 120, the gate insulation film GD, a gate spacer GA, and a gate capping film GC.

In an example embodiment, the gate electrode 120 of the gate structure GS may surround the channel layers CH of the first active pattern AP1 and the channel layers CH′ of the second active pattern AP2. In an example embodiment, the gate electrode 120 may be disposed across the first active area AR1 and the second active area AR2.

In an example embodiment, the gate electrode 120 may be disposed to extend lengthwise in the third direction D3. The gate electrode 120 may be disposed between the first source/drain area 130 and the second source/drain area 140 which are adjacent in the second direction D2 and between the first source/drain area 130′ and the second source/drain area 140′which are adjacent in the second direction D2. Gate electrodes 120 may be disposed to be spaced apart from each other in the second direction D2.

In an example embodiment, the gate electrode 120 may be electrically connected to and/or contact a gate contact plug (not illustrated). At least a portion of the gate electrode 120 may overlap a gate contact plug in the first active area AR1, the second active area AR2, or the field area FR in the first direction D1.

In an example embodiment, the gate electrode 120 may include a conductive material. In the present disclosure, the conductive material may include at least one of a metal, a metal alloy, a conductive metallic nitride, a metallic silicide, a doped semiconductor material, a conductive metallic oxide, and a conductive metallic oxynitride. For example, the conductive material may include at least one selected from a group including titanium nitride (TiN), a tantalum carbide (TaC), Tantalu nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and vanadium (V), but the inventive concept is not limited thereto. The conductive metallic oxide and the conductive metallic oxynitride may include a form in which the above-described substance is oxidized, but the inventive concept is not limited thereto.

In an example embodiment, gate electrodes 120 may be disposed on both side surfaces of the first source/drain areas 130 and 130′ and both side surfaces of the second source/drain areas 140 and 140′. In an example embodiment, at least a portion or some of the gate electrodes 120 may be normal/regular gate electrodes used as gates of transistors, and another portion or some others thereof may be dummy gate electrodes.

In an example embodiment, the gate insulation film GD of the gate structure GS may surround and/or contact at least a portion of the gate electrode 120. The gate insulation film GD may include an insulation material. In an example embodiment, the gate spacer GA may surround and/or contact at least a portion of the gate insulation film GD. The gate spacer GA may include a conductive material. In an example embodiment, a high-dielectric interfacial layer (not illustrated) may be disposed between the gate insulation film GD and the gate spacer GA. The high-dielectric interfacial layer may include, for example, a high-permittivity material. In an example embodiment, the high-permittivity material included in the high-dielectric interfacial layer may have a permittivity higher than those of an insulation material included in the gate spacer GA and an insulation material included in the gate insulation film GD.

In an example embodiment, the gate capping film GC of the gate structure GS may be formed on the gate spacer GA and the gate electrode 120. The gate capping film GC may be disposed on the first active pattern AP1 and the second active pattern AP2. In an example embodiment, the gate capping film GC may include a conductive material.

In an example embodiment, the semiconductor device 10 may include a first frontside inter-layer insulation film FILD_1 to which the gate structure GS is disposed. The first frontside inter-layer insulation film FILD_1 may include an insulation material. The first frontside inter-layer insulation film FILD_1 may include one or more selected from a group including silicon oxide, silicon-germanium oxide, germanium oxide, silicon oxynitride, silicon nitride, and a low-permittivity material.

In an example embodiment, the semiconductor device 10 may include a source/drain etch stop film 150 disposed between the gate structure GS and the first frontside inter-layer insulation film FILD_1, between the first frontside inter-layer insulation film FILD_1 and each of the first source/drain areas 130 and 130′, and between the first frontside inter-layer insulation film FILD_1 and each of the second source/drain areas 140 and 140′. In an example embodiment, the source/drain etch stop film 150 may include at least one selected from a group including silicon nitride (SiN), silicon oxynitride (SiON), silicon oxycarbonitride (SiOCN), silicon boronitride (SiBN), silicon oxyboronitride (SiOBN), and silicon oxycarbide (SiOC).

In an example embodiment, the semiconductor device 10 may include an inner gate structure IGS which is disposed between the channel layers CH or the channel layers CH′. In an example embodiment, each gate structure GS may include the inner gate structure IGS which is disposed between the channel layers CH or the channel layers CH′. In an example embodiment, the inner gate structure IGS may be disposed on the frontside 100FS of the base pattern. In an example embodiment, the inner gate structure IGS may be disposed between the frontside 100FS of the base pattern and each of a lower surface of the first active pattern AP1 and a lower surface of the second active pattern AP2. In an example embodiment, the inner gate structure IGS may be in contact with at least a portion of the channel layers CH and CH′ in the first direction D1 and may be in contact with at least a portion of the first source/drain areas 130 and 130′ and the second source/drain areas 140 and 140′ which will be described below.

In an example embodiment, the inner gate structure IGS may include the gate electrode 120, the gate insulation film GD, and the inner spacer IA. In an example embodiment, the gate insulation film GD may surround at least a portion of the gate electrode 120. In an example embodiment, the inner spacer IA may surround at least a portion of the gate insulation film GD. As an example, the inner spacer IA may be disposed between the gate insulation film GD and each of the first source/drain area 130 and the first source/drain area 130′ and between the gate insulation film GD and each of the second source/drain area 140 and the second source/drain area 140′. In an example embodiment, the inner spacer IA may be disposed between the gate insulation film GD and each of the channel layers CH and CH′. As another example, while being disposed between the gate insulation film GD and each of the first source/drain area 130 and the first source/drain area 130′ and between the gate insulation film GD and each of the second source/drain area 140 and the second source/drain area 140′, the inner spacer IA may not be disposed between the gate insulation film GD and each of the channel layers CH and CH′. The inner spacer IA may include a conductive material. The inner space IA may include a conductive material different from that of the gate insulation film GD.

In an example embodiment, the semiconductor device 10 may not include the inner spacer IA. In this case, each of the first source/drain areas 130 and 130′ and the second source/drain areas 140 and 140′ may be in contact with the gate insulation film GD on side surfaces perpendicular to the second direction D2.

In an example embodiment, the backside contact plugs BCA and BCA′ and the frontside contact plugs FCA and FCA′ may independently include a conductive material. In an example embodiment, the backside contact plugs BCA and BCA′ may be electrically connected to the backside wiring line BWL. In an example embodiment, the backside wiring line BWL may be one of power lines that supply power to the semiconductor device 10. In an example embodiment, the frontside contact plugs FCA and FCA′ may be electrically connected to the frontside wiring via FWV, and the frontside wiring via FWV may be electrically connected to the frontside wiring line FWL. In an example embodiment, the frontside wiring line FWL may be one of signal lines that transfer an electrical signal to the semiconductor device 10. For example, the frontside wiring line FWL may be a signal line receiving electrical signals from the outside of the semiconductor device 10.

In an example embodiment, the frontside contact plugs FCA and FCA′ may be/have a single-layer structure. However, in another example embodiment, the frontside contact plugs FCA and FCA′ may be/have a multilayered structure including frontside contact filling films FCA-f and FCA-f′ and frontside contact barrier films FCA-b and FCA-b′. In an example embodiment, the frontside contact filling films FCA-f and FCA-f′ may include one selected from a group including aluminum (Al), tungsten (W), cobalt (Co), ruthenium (Ru), copper (Cu), silver (Ag), gold (Au), manganese (Mn), and molybdenum (Mo). In an example embodiment, the frontside contact barrier films FCA-b and FCA-b′ may include one selected from a group including tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material.

In the present disclosure, the two-dimensional material may be a metallic material and/or a semiconductor material. The 2D material may include a two-dimensional allotrope or a two-dimensional compound and include, for example, at least one of graphene, molybdenum disulfide (MoS2), molybdenum diselenide (MoSe2), tungsten diselenide (WSe2), and tungsten disulfide (WS2), but the inventive concept is not limited thereto. For example, since the above-described 2D materials are mentioned as examples, 2D materials that may be included in the semiconductor device 10 of the present disclosure are not limited to the above-described materials.

In an example embodiment, the semiconductor device 10 may include a second frontside inter-layer insulation film FILD_2 that is disposed on the first frontside inter-layer insulation film FILD_1 and to which the frontside wiring via FWV is disposed. In an example embodiment, the frontside wiring via FWV may be/have a single-layer structure. However, in another example embodiment, the frontside wiring via FWV may be/have a multilayered structure including a frontside via filling film FWV-f and a frontside via barrier film FWV-b. In an example embodiment, the above-described material included in the frontside contact filling films FCA-f and FCA-f′ may be referenced/used for a material included in the frontside via filling film FWV-f, and the above-described material included in the frontside contact barrier films FCA-b and FCA-b′ may be referenced/used for a material included in the frontside via barrier film FWV-b.

In an example embodiment, a first etch stop film 160 may be disposed between the second frontside inter-layer insulation film FILD_2 and the first frontside inter-layer insulation film FILD_1 in the semiconductor device 10 in some cases. In an example embodiment, the first etch stop film 160 may be disposed between the second frontside inter-layer insulation film FILD_2 and the first frontside inter-layer insulation film FILD_1 and between the second inter-layer insulation film FILD_2 and the source/drain etch stop film 150. In an example embodiment, the frontside wiring via FWV may penetrate the first etch stop film 160 and may be electrically connected to the frontside contact plug FCA due thereto. In an example embodiment, the above-described material included in the source/drain etch stop 150 film may be referenced/used for a material included in and/or forming the first etch stop film 160.

In an example embodiment, the semiconductor device 10 may include a third frontside inter-layer insulation film FILD_3 that is disposed on the second frontside inter-layer insulation film FILD_2 and to which at least a portion of the frontside wiring line FWL is disposed. In an example embodiment, the frontside wiring line FWL may be/have a single-layer structure. However, in another example embodiment, the frontside wiring line FWL may be/have a multilayered structure including a frontside wiring filling film FWL-f and a frontside wiring barrier film FWL-b. In an example embodiment, the above-described material included in the frontside contact filling films FCA-f and FCA-f′ may be referenced/used for a material included in the frontside wiring filling film FWL-f, and the above-described material included in the frontside contact barrier films FCA-b and FCA-b′ may be referenced/used for a material included in the frontside wiring barrier film FWL-b.

In an example embodiment, a second etch stop film 170 may be disposed between the third frontside inter-layer insulation film FILD_3 and the second frontside inter-layer insulation film FILD_2 in the semiconductor device 10 in some cases. In an example embodiment, the second etch stop film 170 may be disposed between the third frontside inter-layer insulation film FILD_3 and the second frontside inter-layer insulation film FILD_2. In an example embodiment, the frontside wiring line FWL may penetrate the second etch stop film 170 and may be electrically connected to the frontside wiring via FWV due thereto. In an example embodiment, the above-described material included in the source/drain etch stop film 150 may be referenced/used for a material included in the second etch stop film 170. In an example embodiment, the second frontside inter-layer insulation film FILD_2 and the third frontside inter-layer insulation film FILD_3 may be one body, and in this case, the above-described second etch stop film 170 may be absent.

In an example embodiment, the backside contact plugs BCA and BCA′ may be electrically connected to and/or contact the first source/drain areas 130 and 130′ from a backside 100BS of the base pattern opposite to the frontside 100FS of the base pattern. The backside 100BS of the base pattern may be a lower surface of the base pattern, and the frontside 100FS of the base pattern may be an upper surface of the base pattern. In an example embodiment, a backside contact plug BCA in the first active area AR1 may be electrically connected to and/or contact the first source/drain area 130 from the backside 100BS of the base pattern. In an example embodiment, a backside contact plug BCA′ in the second active area AR2 may be electrically connected to and/or contact the first source/drain area 130′ from the backside 100BS of the base pattern.

In an example embodiment, the frontside contact plugs FCA and FCA′ may be electrically connected to and/or contact the second source/drain areas 140 and 140′ on the frontside 100FS of the base pattern. In an example embodiment, the frontside contact plug FCA in the first active area AR1 may be electrically connected to and/or contact the second source/drain area 140 on the frontside 100FS of the base pattern. In an example embodiment, a frontside contact plug FCA′ in the second active area AR2 may be electrically connected to and/or contact the second source/drain area 140′ from the frontside 100FS of the base pattern.

In an example embodiment, the frontside contact plugs FCA and FCA′ may be electrically connected to and/or contact the second source/drain areas 140 and 140′ by penetrating the first frontside inter-layer insulation film FILD_1. In an example embodiment, the frontside contact plugs FCA and FCA′ may be connected to and/or contact the second source/drain areas 140 and 140′ by penetrating the first frontside inter-layer insulation film FILD_1 and the source/drain etch stop film 150.

In an example embodiment, the backside contact plugs BCA and BCA′ in the active areas AR1 and AR2 may be spaced apart from the first-first layers 131 and 131′. In an example embodiment, the backside contact plug BCA in the first active area AR1 may be spaced apart from the first-first layer 131 of the first active pattern AP1. In an example embodiment, the backside contact plug BCA′ in the second active area AR2 may be spaced apart from the first-first layer 131′ of the second active pattern AP2. Through this, contact resistances R_{cnt} at contact areas at which the backside contact plugs BCA and BCA′ are in contact with the first source/drain areas 130 and 130′ may be minimized.

In an example embodiment, the backside contact plugs BCA and BCA′ in the active areas AR1 and AR2 may be electrically connected to and/or contact the first-second layers 132 and 132′ while being spaced apart from the first-first layers 131 and 131′. In an example embodiment, the backside contact plug BCA in the first active area AR1 may be electrically connected to and/or contact the first-second layer 132 while being spaced apart from the first-first layer 131 of the first active pattern AP1. In an example embodiment, the backside contact plug BCA′ in the second active area AR2 may be electrically connected to and/or contact the first-second layer 132′ while being spaced apart from the first-first layer 131′ of the second active pattern AP2.

In an example embodiment, each of the first-first layer 131 and the first-second layer 132 of the first active pattern AP1 may include an impurity. In an example embodiment, an impurity concentration of the first-second layer 132 may be higher than an impurity concentration of the first-first layer 131. In an example embodiment, the impurity concentration of the first-second layer 132 may be greater than or equal to three times the impurity concentration of the first-first layer 131. In an example embodiment, each of the first-first layer 131′ and the first-second layer 132′ of the second active pattern AP2 may include an impurity. In an example embodiment, a concentration of the impurity of the first-second layer 132′ may be higher than a concentration of the impurity of the first-first layer 131′. In an example embodiment, the concentration of the impurity of the first-second layer 132′ may be greater than or equal to three times the concentration of the impurity of the first-first layer 131′.

In an example embodiment, the backside contact plug BCA in the first active area AR1 may include a first area BCA-1 surrounded by and/or horizontally overlapping the first-second layer 132 and a second area BCA-2 that is an area other than the first area BCA-1. Here, the semiconductor device 10 may include a backside silicide layer BSC in contact with the first-second layer 132 on the first area BCA-1 of the backside contact plug BCA. In an example embodiment, the backside silicide layer BSC in the first active area AR1 may be spaced apart from the first-first layer 131 and may be in contact with the first-second layer 132.

In an example embodiment, the backside contact plug BCA′ of the second active area AR2 may include a first area BCA′-1 surrounded by and/or horizontally overlapping the first-second layer 132′ and a second area BCA′-2 that is an area other than the first area BCA′-1. Here, the semiconductor device 10 may include a backside silicide layer BSC′ in contact with the first-second layer 132′ on the first area BCA′-1 of the backside contact plug BCA′. In an example embodiment, the backside silicide layer BSC′ in the second active area AR2 may be spaced apart from the first-first layer 131′ and may be in contact with the first-second layer 132′.

In an example embodiment, backside silicide layers BSC and BSC′ may include a metallic silicide and allow the backside contact plugs BCA and BCA′ to be in ohmic contact with the first source/drain areas 130 and 130′.

In an example embodiment, in the first active area AR1, and in the first area BCA-1 of the backside contact plug BCA, a maximum length in the second direction D2 of the backside contact plug BCA may be shorter than that of the first-second layer 132. In an example embodiment, in the second active area AR2, and in the first area BCA′-1 of the backside contact plug BCA′, a maximum length in the second direction D2 of the backside contact plug BCA′ may be shorter than that of the first-second layer 132′.

In an example embodiment, at least a portion of the first-first layer 131 of the first active pattern AP1 may be disposed to be conformal on the side surfaces of the channel layers CH. In an example embodiment, an interface between a channel layer CH and the first-first layer 131 and an interface between the first-first layer 131 and the first-second layer 132 may be parallel or substantially parallel. In an example embodiment, at least a portion of the first-first layer 131′ of the second active pattern AP2 may be disposed to be conformal on the side surfaces of the channel layers CH′. In an example embodiment, an interface between a channel layer CH′ and the first-first layer 131′ and an interface between the first-first layer 131′ and the first-second layer 132′ may be parallel or substantially parallel. Through this, the first source/drain areas 130 and 130′ may apply sufficient quantum stress to the channel layers CH and CH′ to improve a degree of movement of an electron in the channel layers CH and CH′.

In an example embodiment, as approaching the frontside 100FS of the base pattern, a length or width in the second direction D2 of an end portion of the first-first layer 131 of the first active pattern AP1, which is adjacent to the frontside 100FS of the base pattern, may be gradually decreased. In an example embodiment, as approaching the frontside 100FS of the base pattern, a length or width in the second direction D2 of an end portion of the first-first layer 131′ of the second active pattern AP2, which is adjacent to the frontside 100FS of the base pattern, may be gradually decreased.

In an example embodiment, the end portion of the first-first layer 131 of the first active pattern AP1 may have a sloped or an inclined surface 131lc based on or with respect to the side surfaces of the channel layers CH, and a slope angle Θ of the sloped surface 131lc with respect to the side surfaces of the channel layers CH may be an acute angle. In an example embodiment, the end portion of the first-first layer 131′ of the second active pattern AP2 may have a sloped or an inclined surface based on or with respect to the side surfaces of the channel layers CH′, and a slope angle of the sloped surface with respect to the side surfaces of the channel layers CH′ may be an acute angle. Through this, allowing the backside contact plugs BCA and BCA′ not to be in contact with the first-first layers 131 and 131′ may be facilitated.

In an example embodiment, the frontside contact plugs FCA and FCA′ in the active areas AR1 and AR2 may be spaced apart from the second-first layers 141 and 141′. In an example embodiment, the frontside contact plug FCA in the first active area AR1 may be spaced apart from the second-first layer 141 of the first active pattern AP1. In an example embodiment, the frontside contact plug FCA′ in the second active area AR2 may be spaced apart from the second-first layer 141′ of the second active pattern AP2. Through this, contact resistances R_{cnt} at contact areas at which the frontside contact plugs FCA and FCA′ are in contact with the second source/drain areas 140 and 140′ may be minimized.

In an example embodiment, the frontside contact plugs FCA and FCA′ in the active areas AR1 and AR2 may be electrically connected to and/or contact the second-second layers 142 and 142′ while being spaced apart from the second-first layers 141 and 141′. In an example embodiment, the frontside contact plug FCA in the first active area AR1 may be electrically connected to and/or contact the second-second layer 142 while being spaced apart from the second-first layer 141 of the first active pattern AP1. In an example embodiment, the frontside contact plug FCA′ in the second active area AR2 may be electrically connected to and/or contact the second-second layer 142′ while being spaced apart from the second-first layer 141′ of the second active pattern AP2.

In an example embodiment, each of the second-first layer 141 and the second-second layer 142 of the first active pattern AP1 may include an impurity. In an example embodiment, a concentration of the impurity of the second-second layer 142 may be higher than a concentration of the impurity of the second-first layer 141. In an example embodiment, the concentration of the impurity of the second-second layer 142 may be greater than or equal to three times the concentration of the impurity of the second-first layer 141. In an example embodiment, each of the second-first layer 141′ and the second-second layer 142′ of the second active pattern AP2 may include an impurity. In an example embodiment, a concentration of the impurity of the second-second layer 142′ may be higher than a concentration of the impurity of the second-first layer 141′. In an example embodiment, the concentration of the impurity of the second-second layer 142′ may be greater than or equal to three times the concentration of the impurity of the second-first layer 141′.

In an example embodiment, the frontside contact plug FCA in the first active area AR1 may include a first area FCA-1 surrounded by and/or horizontally overlapping the second-second layer 142 and a second area FCA-2 that is an area other than the first area FCA-1. Here, the semiconductor device 10 may include a frontside silicide layer FSC in contact with the second-second layer 142 on the first area FCA-1 of the frontside contact plug FCA. In an example embodiment, the frontside silicide layer FSC in the first active area AR1 may be spaced apart from the second-first layer 141 and may be in contact with the second-second layer 142.

In an example embodiment, the frontside contact plug FCA′ in the second active area AR2 may include a first area FCA′-1 surrounded by and/or horizontally overlapping the second-second layer 142′ and a second area FCA′-2 that is an area other than the first area FCA′-1. Here, the semiconductor device 10 may include a frontside silicide layer FSC′ in contact with the second-second layer 142′ on the first area FCA′-1 of the frontside contact plug FCA′. In an example embodiment, the frontside silicide layer FSC′ in the second active area AR2 may be spaced apart from the second-first layer 141′ and may be in contact with the second-second layer 142′.

In an example embodiment, frontside silicide layers FSC and FSC′ may include a metallic silicide and allow the frontside contact plugs FCA and FCA′ to be in ohmic contact with the second source/drain areas 140 and 140′.

In an example embodiment, in the first active area AR1, and in the first area FCA-1 of the frontside contact plug FCA, a maximum length or width in the second direction D2 of the frontside contact plug FCA may be shorter than that of the second-second layer 142. In an example embodiment, in the second active area AR2, and in the first area FCA′-1 of the frontside contact plug FCA′, a maximum length or width in the second direction D2 of the frontside contact plug FCA′ may be shorter than that of the second-second layer 142′.

In an example embodiment, at least a portion of the second-first layer 141 of the first active pattern AP1 may be disposed to be conformal on the side surfaces of the channel layers CH. In an example embodiment, an interface between the channel layer CH and the second-first layer 141 and an interface between the second-first layer 141 and the second-second layer 142 may be parallel or substantially parallel. In an example embodiment, at least a portion of the second-first layer 141′ of the second active pattern AP2 may be disposed to be conformal on the side surfaces of the channel layers CH′. In an example embodiment, an interface between the channel layer CH′ and the second-first layer 141′ and an interface between the second-first layer 141′ and the second-second layer 142′ may be parallel or substantially parallel. Through this, the second source/drain areas 140 and 140′ may apply sufficient quantum stress to the channel layers CH and CH′ to improve the degree of the movement of the electron in the channel layers CH and CH′.

In an example embodiment, as approaching the frontside 100FS of the base pattern, a length or width in the second direction D2 of an end portion (e.g., a bottom end portion) of the second-first layer 141 of the first active pattern AP1, which is adjacent to the frontside 100FS of the base pattern, may be gradually decreased. In an example embodiment, as approaching the frontside 100FS of the base pattern, a length or width in the second direction D2 of an end portion (e.g., a bottom end portion) of the first-first layer 141′ of the second active pattern AP2, which is adjacent to the frontside 100FS of the base pattern, may be gradually decreased.

In an example embodiment, the end portion of the second-first layer 141 of the first active pattern AP1 may have a sloped or an inclined surface based on or with respect to the side surfaces of the channel layers CH, and a slope angle Θ of the sloped surface with respect to the side surfaces of the channel layers CH may be an acute angle. In an example embodiment, the end portion of the second-first layer 141′ of the second active pattern AP2 may have a sloped or an inclined surface based on or with respect to the side surfaces of the channel layers CH′, and a slope angle Θ of the sloped surface with respect to the side surfaces of the channel layers CH′ may be an acute angle.

In an example embodiment, the semiconductor device 10 may include, on the frontside 100FS of the base pattern, supporters 110 and 110′ extended, e.g., lengthwise, in the first direction D1 and connected to and/or contact the second source/drain areas 140 and 140′ in the first direction D1 at portions opposite to portions to which the frontside contact plugs FCA and FCA′ are connected. In an example embodiment, the supporters 110 and 110′ may include silicon (Si) or silicon-germanium (SiGe), but the inventive concept is not limited thereto.

In an example embodiment, a concentration of an impurity of a supporter 110 in the first active area AR1 may be higher than the concentration of the impurity of the second-first layer 141. In an example embodiment, the concentration of the impurity of the supporter 110 may be greater than or equal to two times the concentration of the impurity of the second-first layer 141. In an example embodiment, a concentration of an impurity of a supporter 110′ in the second active area AR2 may be higher than the concentration of the impurity of the second-first layer 141′. In an example embodiment, the concentration of the impurity of the supporter 110′ may be greater than or equal to two times the concentration of the impurity of the second-first layer 141′.

In an example embodiment, the concentration of the impurity of the second-second layer 142 of the first active pattern AP1 may be higher than the concentration of the impurity of the supporter 110. In an example embodiment, the concentration of the impurity of the second-second layer 142′ of the second active pattern AP2 may be higher than the concentration of the impurity of the supporter 110′.

In an example embodiment, the supporters 110 and 110′ may be in contact with the second-second layers 142 and 142′. In an example embodiment, when viewed in the first direction D1, the supporters 110 and 110′ may not overlap the second-first layers 141 and 141′. For example, the supporters 110 and 110′ may not vertically overlap the second-first layers 141 and 141′. In an example embodiment, the supporter 110 in the first active area AR1 may be in contact with the second-second layer 142, and when viewed in the first direction D1, the second-first layer 141 and the supporter 110 may not overlap. For example, the second-first layer 141 and the supporter 110 may not vertically overlap each other. In an example embodiment, the supporter 110′ in the second active area AR2 may be in contact with the second-second layer 142′, and when viewed in the first direction D1, the second-first layer 141′ and the supporter 110′ may not overlap. For example, the second-first layer 141′ and the supporter 110′ may not vertically overlap each other.

In FIG. 9, the gate insulation film GD and the inner spacer IA which are disposed between the gate electrode 120 and each of the channel layers CH and CH′ have been omitted for ease of illustration.

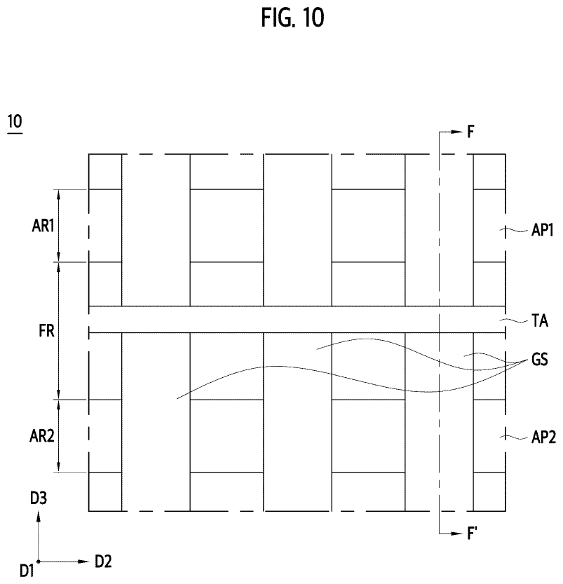

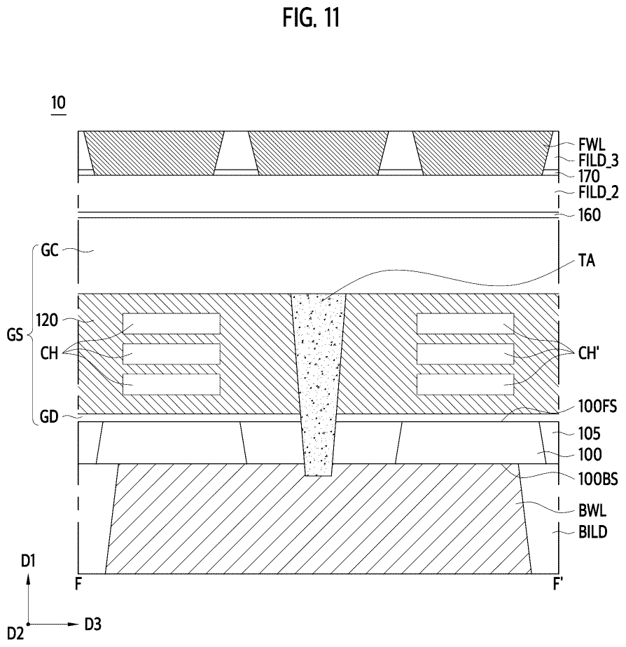

FIG. 10 is an example layout diagram illustrating a semiconductor device according to an example embodiment of the present disclosure. FIG. 11 is an example diagram illustrating a cross section taken along a line F-F′ of FIG. 10. In FIG. 11, the gate insulation film GD and the inner spacer IA which are disposed between the gate electrode 120 and each of the channel layers CH and CH′ have been omitted for ease of illustration.

In an example embodiment, the field area FR may include a trench area TA. In an example embodiment, the trench area TA may have a shallow trench isolation (STI) structure, but the inventive concept is not limited thereto. For example, the field area FR may be defined by the trench area TA. In an example embodiment, the trench area TA may be disposed between the first active area AR1 and the second active area AR2 which are spaced apart from each other in the third direction D3 and may be extended in the second direction D2.

In an example embodiment, at least a portion of the gate structure GS may not be continuously extended across the first active area AR1 and the second active area AR2 in the third direction D3 and may be separated in the field area FR. For example, the gate electrode 120 may be cut by the trench area TA in the field area FR. In such a case, the gate structure GS which is extended in the third direction D3 and crosses the first active area AR1 and the gate structure GS which is extended in the third direction D3 and crosses the second active area AR2 may be spaced apart from each other in the third direction D3.

In an example embodiment, an already known methods may be applied to a method of fabricating the semiconductor device 10 as long as the known methods are compatible with the description of the present disclosure. Hereinafter, a method for securing/manufacturing the above-described structural property of the semiconductor device 10 will be mainly described. In addition, the first active pattern AP1 will be described below as a reference for convenience, but it is apparent to those skilled in the art that a description thereof may be similarly applied to the second active pattern AP2. For example, the description with respect to the first active pattern AP1 below may also be applied to the second active pattern AP2.

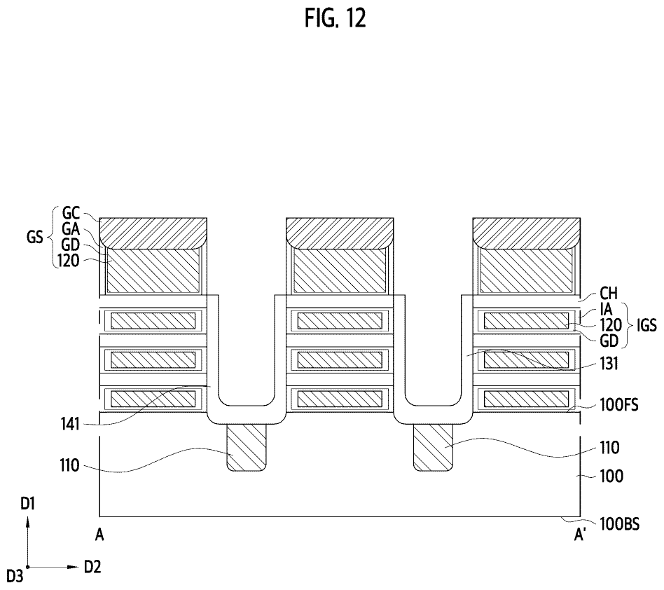

FIG. 12 is a diagram illustrating a cross section taken along the line A-A′ of FIG. 1 and an example diagram illustrating a shape in a step of a manufacturing process of the semiconductor device 10 in which the first-first layer 131 and the second-first layer 141 are grown. In an example embodiment the first-first layer 131 and the second-first layer 141 may be grown through an epitaxial growth scheme/process.

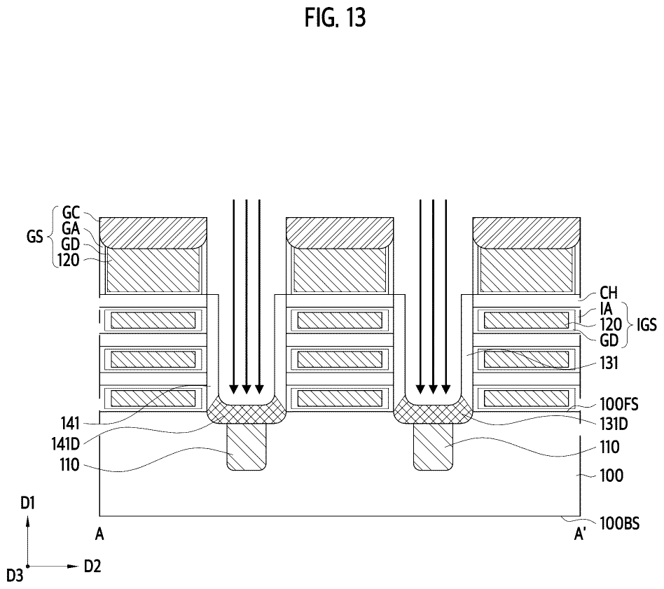

FIG. 13 is a diagram illustrating a cross section taken along the line A-A′ of FIG. 1 and an example diagram illustrating a shape in a step of the manufacturing process in which a damaged first-first layer 131D and a damaged second-first layer 141D are formed by damaging a portion of the first-first layer 131 and the second-first layer 141 through an ion implantation process (IIP). In an example embodiment, the damaged first-first layer 131D and the damaged second-first layer 141D which are easily removable may be formed through ion implantation. The damaged first-first layer 131D and the damaged second-first layer 141D may be in a state in which crystallinity of the layers is damaged due to the ion implantation. The damaged first-first layer 131D and the damaged second-first layer 141D may be removed, through etching or the like, easier than the first-first layer 131 and the second-first layer 141 which are undamaged. An element used in the ion implantation may be boron (B) or phosphorus (P), but the inventive concept is not limited thereto.

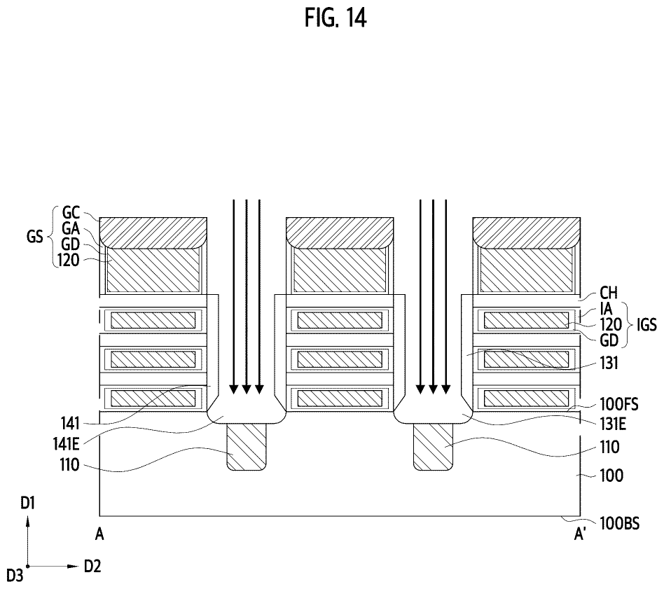

FIG. 14 is a diagram illustrating a cross section taken along the line A-A′ of FIG. 1 and an example diagram illustrating a shape in a step of the manufacturing process in which the damaged first-first layer 131D and the damaged second-first layer 141D which are damaged through an ion implantation process (IIP) are removed. In an example embodiment, the damaged first-first layer 131D and the damaged second-first layer 141D may be removed through an etch back scheme/process, so that an area 131E from which the damaged first-first layer 131D is removed and an area 141E from which the damaged second-first layer 141D is removed are formed. In this process, the supporter 110 may be partially etched from an upper portion.

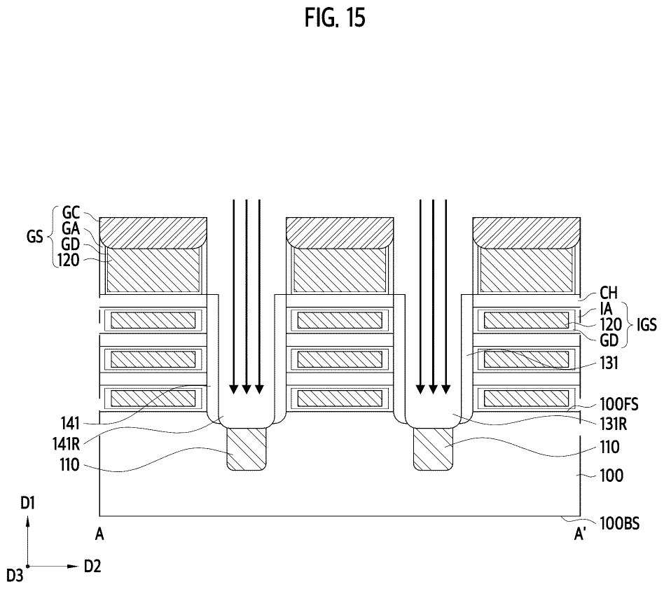

FIG. 15 is a diagram illustrating a cross section taken along the line A-A′ of FIG. 1 and an example diagram illustrating a shape in a step of a manufacturing process in which a recessed first-first layer 131R and a recessed second-first layer 141R are formed by removing a portion of the first-first layer 131 and a portion of the second-first layer 141 through an etching process. Unlike a scheme/process of the ion implantation process described above with respect to FIGS. 13 and 14, an etching scheme/process may be used in a process shown in FIG. 15. In this process, the supporter 110 may be partially etched from an upper portion.

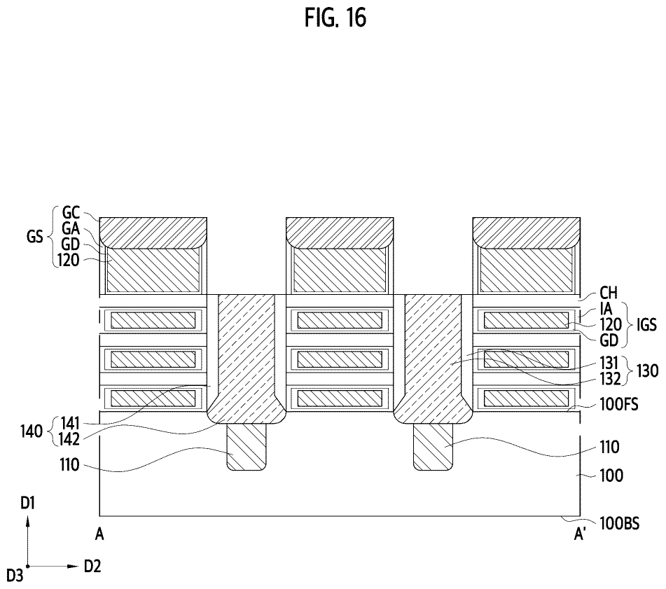

FIG. 16 is a diagram illustrating a cross section taken along the line A-A′ of FIG. 1 and an example diagram illustrating a shape in a step of a manufacturing process in which the first-second layer 132 and the second-second layer 142 are grown. A structure and a property of the semiconductor device 10 may be secured by growing the first-second layer 132 and the second-second layer 142 in a structure illustrated in each of FIGS. 14 and 15. Through this, the semiconductor device 10 which minimizes a contact resistance R_{cnt} at a contact area at which the backside contact plug BCA is in contact with the first source/drain area 130 and in which the first source/drain area 130 and the second source/drain area 140 apply sufficient quantum stress to improve a degree of movement of an electron in the channel layers CH and CH′ may be provided.

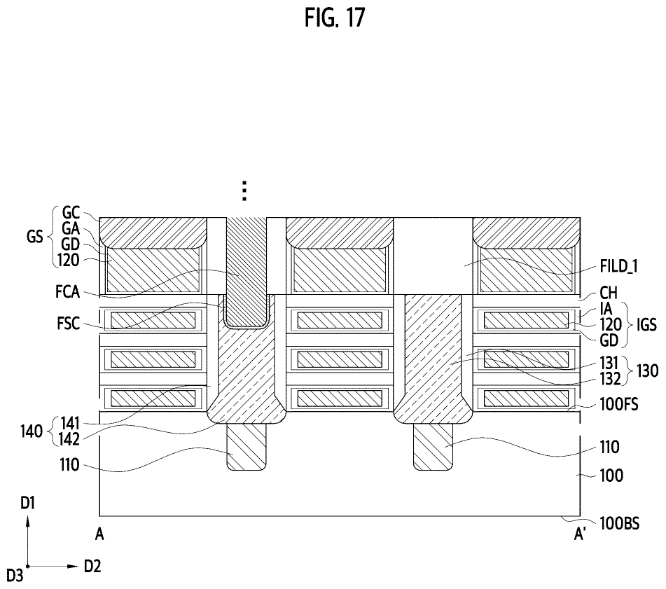

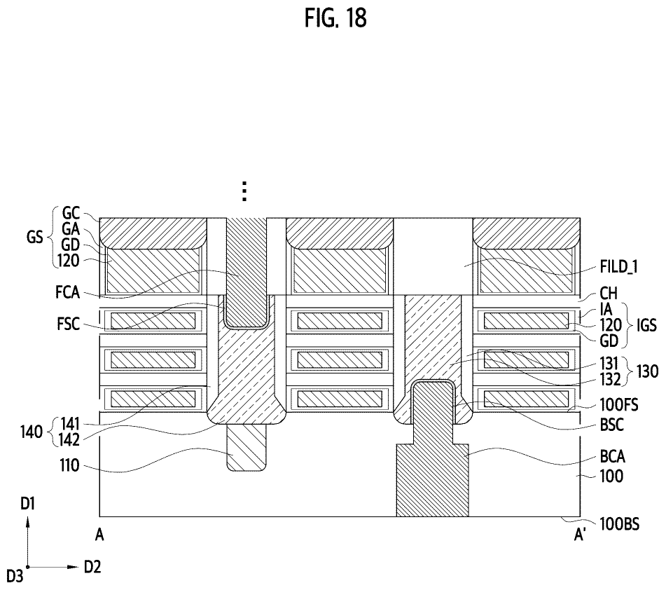

FIG. 17 is a diagram illustrating a cross section taken along the line A-A′ of FIG. 1 and an example diagram illustrating a shape of a step of a manufacturing process in which the frontside contact plug FCA is formed on the second-second layer 142. FIG. 18 is a diagram illustrating a cross section taken along the line A-A′ of FIG. 1 and an example diagram illustrating a shape of a step of the manufacturing process in which the backside contact plug BCA is formed on the first-second layer 132. In an example embodiment, a portion of the first frontside inter-layer insulation film FILD_1 and a portion of the second-second layer 142 may be etched through a photolithography process or the like, and the frontside contact plug FCA may be disposed/formed in an etched area. In an example embodiment, the frontside silicide layer FSC may be formed earlier before the frontside contact plug FCA is formed/disposed. In an example embodiment, in this process, and in order to form/dispose the backside contact plug BCA on the first-second layer 132, the semiconductor device 10 in a semi-finished state may be flipped, a portion of the supporter 110 and the first-second layer 132 and a portion of the backside inter-layer insulation film BILD (see FIG. 7) may be etched through a photolithography process or the like, and the backside contact plug BCA may be formed/disposed in an etched area. In an example embodiment, the backside silicide layer BSC may be formed earlier before the backside contact plug BCA is formed/disposed.

According to example embodiments, a semiconductor device minimizes a contact resistance at a contact area at which a backside contact plug is in contact with a source/drain area and the source/drain area applies sufficient quantum stress to improve a degree of movement of an electron in channel layers.

Effects of the present disclosure are not limited to those described above and other effects may be apparent to those skilled in the art from the foregoing description and the accompanying claims.

The example embodiments have been described with reference to the accompanying drawings above. However, the present disclosure is not limited to the above example embodiments and may be manufactured in various forms different from each other. Those skilled in the art to which the present disclosure belongs may understand that other embodiments may be implemented without changing the technical spirit or the characteristics of the present disclosure. Therefore, in all aspects, the above-described example embodiments should be understood as examples and not as being limitative. For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

What is claimed is:

1. A semiconductor device comprising:
a base pattern;
channel layers disposed to be spaced apart from each other in a first direction perpendicular to a frontside of the base pattern on the frontside of the base pattern;
an inner gate structure disposed between the channel layers;
a first source/drain area electrically connected to the channel layers on the frontside of the base pattern;
a second source/drain area spaced apart from the first source/drain area in a second direction crossing the first direction and electrically connected to the channel layers on the frontside of the base pattern;
a backside contact plug electrically connected to the first source/drain area from a backside of the base pattern opposite to the frontside of the base pattern; and
a frontside contact plug electrically connected to the second source/drain area on the frontside of the base pattern,
wherein the first source/drain area comprises:
a first-first layer disposed on side surfaces of the channel layers, the side surfaces of the channel layers being perpendicular to the second direction; and
a first-second layer disposed on the first-first layer, and
the backside contact plug is spaced apart from the first-first layer.

2. The semiconductor device of claim 1, wherein each of the first-first layer and the first-second layer comprises an impurity, and
a concentration of the impurity of the first-second layer is higher than a concentration of the impurity of the first-first layer.

3. The semiconductor device of claim 1, wherein the backside contact plug comprises:
a first area surrounded by the first-second layer; and
a second area other than the first area, and
the semiconductor device further comprises a backside silicide layer in contact with the first-second layer on the first area of the backside contact plug.

4. The semiconductor device of claim 3, wherein the backside silicide layer is spaced apart from the first-first layer.

5. The semiconductor device of claim 3, wherein, in the first area of the backside contact plug, a maximum length in the second direction of the backside contact plug is shorter than that of the first-second layer.

6. The semiconductor device of claim 1, wherein at least a portion of the first-first layer is disposed to be conformal on the side surfaces of the channel layers.

7. The semiconductor device of claim 6, wherein as approaching the frontside of the base pattern, a length in the second direction of an end portion of the first-first layer adjacent to the frontside of the base pattern is gradually decreased.

8. The semiconductor device of claim 7, wherein the end portion of the first-first layer has a sloped surface based on the side surfaces of the channel layers, and
a slope angle of the sloped surface with respect to the side surfaces of the channel layers is an acute angle.

9. The semiconductor device of claim 1, wherein the second source/drain area comprises:
a second-first layer disposed on the side surfaces of the channel layers; and
a second-second layer disposed on the second-first layer, and
the frontside contact plug is spaced apart from the second-first layer.

10. The semiconductor device of claim 9, wherein the frontside contact plug comprises:
a first area surrounded by the second-second layer; and
a second area other than the first area, and
the semiconductor device further comprises a frontside silicide layer in contact with the second-second layer on the first area of the frontside contact plug.

11. The semiconductor device of claim 10, wherein the frontside silicide layer is spaced apart from the second-first layer.

12. The semiconductor device of claim 10, wherein, in the first area of the frontside contact plug, a maximum length in the second direction of the frontside contact plug is shorter than that of the first-second layer.

13. The semiconductor device of claim 9, further comprising, on the frontside of the base pattern, a supporter extended in the first direction and connected to the second source/drain area in the first direction at a portion opposite to a portion to which the frontside contact plug is connected.

14. The semiconductor device of claim 13, wherein each of the second-first layer, the second-second layer, and the supporter comprises an impurity,
a concentration of the impurity of the second-second layer is higher than a concentration of the impurity of the supporter, and
the concentration of the impurity of the supporter is higher than a concentration of the impurity of the second-first layer.

15. The semiconductor device of claim 13, wherein the supporter is in contact with the second-second layer, and
the second-first layer and the supporter do not vertically overlap each other.

16. The semiconductor device of claim 9, wherein at least a portion of the second-first layer is disposed to be conformal on the side surfaces of the channel layers.

17. A semiconductor device comprising:
a base pattern;
a first active pattern formed in a first active area extending in a second direction on a frontside of the base pattern;
a second active pattern spaced apart from the first active pattern in a third direction crossing the second direction and formed in a second active area extending in the second direction on the frontside of the base pattern;
gate structures disposed to be spaced apart from each other in the second direction on the frontside of the base pattern and crossing each of the first active pattern and the second active pattern, each of the gate structures including an inner gate structure;
a backside contact plug; and
a frontside contact plug,
wherein each of the first active pattern and the second active pattern comprises:
channel layers disposed to be spaced apart from each other in a first direction crossing the second direction and the third direction on the frontside of the base pattern;
a first source/drain area connected to the channel layers on the frontside of the base pattern; and
a second source/drain area spaced apart from the first source/drain area in the second direction and connected to the channel layers on the frontside of the base pattern,
the inner gate structure is disposed between the channel layers,
the backside contact plug is connected to the first source/drain area from a backside of the base pattern opposite to the frontside of the base pattern,
the frontside contact plug is connected to the second source/drain area on the frontside of the base pattern,
each of the first source/drain area of the first active pattern and the first source/drain area of the second active pattern comprises:
a first-first layer disposed on a side surface of each of the channel layers, the side surface of each of the channel layers being perpendicular to the second direction; and
a first-second layer disposed on the first-first layer,
the backside contact plug in the first active area is spaced apart from the first-first layer of the first source/drain area, and
the backside contact plug in the second active area is spaced apart from the first-first layer of the second source/drain area.

18. The semiconductor device of claim 17, wherein distances between adjacent gate structures are equal to each other.

19. The semiconductor device of claim 17, further comprising a trench area disposed between the first active pattern and the second active pattern, spaced apart from each of the first active pattern and the second active pattern in the third direction, and extended in the second direction.

20. A semiconductor device comprising:
a base pattern;
a first active pattern formed in a first active area extending in a second direction on a frontside of the base pattern;
a second active pattern spaced apart from the first active pattern in a third direction crossing the second direction and formed in a second active area extending in the second direction on the frontside of the base pattern;
gate structures disposed to be spaced apart from each other in the second direction on the frontside of the base pattern and crossing each of the first active pattern and the second active pattern, the gate structures including an inner gate structure;
a backside contact plug; and
a frontside contact plug,
wherein each of the first active pattern and the second active pattern comprises:
channel layers disposed to be spaced apart from each other in a first direction crossing the second direction and the third direction on the frontside of the base pattern;
a first source/drain area contacting the channel layers on the frontside of the base pattern; and
a second source/drain area spaced apart from the first source/drain area in the second direction and contacting the channel layers on the frontside of the base pattern,
the inner gate structure is disposed between the channel layers,
the backside contact plug contacts the first source/drain area from a backside of the base pattern opposite to the frontside of the base pattern,
the frontside contact plug contacts the second source/drain area on the frontside of the base pattern,
each of the first source/drain area of the first active pattern and the first source/drain area of the second active pattern comprises:
a first-first layer comprising an impurity and disposed on a side surface of each of the channel layers, the side surface being perpendicular to the second direction; and
a first-second layer disposed on the first-first layer and comprising an impurity of which a concentration is higher than that of the first-first layer,
the backside contact plug in the first active area is spaced apart from the first-first layer of the first source/drain area,
the backside contact plug in the second active area is spaced apart from the first-first layer of the second source/drain area,
at least a portion of the first-first layer of the first source/drain area is disposed to be conformal on side surfaces of the channel layers,
as approaching the frontside of the base pattern, a length in the second direction of an end portion of the first-first layer of the first source/drain area, which is adjacent to the frontside of the base pattern, is gradually decreased,
the end portion of the first-first layer of the first source/drain area has a sloped surface having an acute slope angle with respect to the side surfaces of the channel layers,
at least a portion of the first-first layer of the second source/drain area is disposed to be conformal on the side surfaces of the channel layers,
as approaching the frontside of the base pattern, a length in the second direction of an end portion of the first-first layer of the second source/drain area, which is adjacent to the frontside of the base pattern, is gradually decreased, and
the end portion of the first-first layer of the second source/drain area has a sloped surface having an acute slope angle with respect to the side surfaces of the channel layers.
